(19) United States
(12) Patent Application Publication
(10) Pub. No.: US 2021/0148962 A1
(43) Pub. Date: May 20, 2021

(54) REFLECTOMETRY SYSTEM FOR ANALYZING FAULTS IN A TRANSMISSION LINE

(71) Applicant: COMMISSARIAT A L'ENERGIE ATOMIQUE ET AUX ENERGIES ALTERNATIVES, PARIS (FR)

(72) Inventors: Esteban CABANILLAS, ORSAY (FR); Christophe LAYER, PARIS (FR)

(21) Appl. No.: 16/627,158

(22) PCT Filed: Jun. 20, 2018
(86) PCT No.: PCT/EP2018/066461

§ 371 Date: Dec. 27, 2019

(30) Foreign Application Priority Data
Jun. 30, 2017 (FR) 1756097

(51) Int. Cl. G01R 31/08; G01R 31/10

(52) U.S. Cl. CPC G01R 31/088; G01R 31/10

(57) ABSTRACT

A reflectometry system includes an amplifier of the signal to be injected into the cable to be analyzed and that incorporates a mechanism for correcting for the non-linear effect of the amplifier without significantly increasing the bulk of the system by limiting the number of additional components to be incorporated with respect to a system without correction of the non-linear effect.

The invention relates to the field of systems for diagnosing wires based on the principle of reflectometry. It more precisely relates to such a system into which is incorporated an amplifier of the signal to be injected into the transmission line to be analyzed. The invention aims to provide a solution allowing the non-linear effect induced by an amplifier on the signal to be injected to be compensated for.

Cables for supplying power or transmitting information are ubiquitous in all electrical systems. These cables are subject to the same stresses as the systems that they connect and may be subject to failures. It is therefore necessary to be able to analyze their state and to deliver information on the detected faults in these cables, this information not only including whether or not there are any faults but also their location and type. Fault analysis may be used to assist with maintenance of the cables. Conventional reflectometry methods allow this type of analysis.

Reflectometry methods use a principle similar to that of radar: an electrical signal, the probe signal or reference signal, is injected into the cable to be tested in one or more places. The signal propagates through the cable or the network cables and some of its energy is reflected when it encounters an electrical discontinuity. An electrical discontinuity may result, for example, from a connection, from the end of the cable or from a fault or more generally from a break in the conditions of propagation of the signal through the cable. Such a break results in a fault that modifies the characteristic impedance of the cable locally, thereby generating a discontinuity in its parameters per unit length.

Analysis of the signals returned to the point of injection allows information on the presence and location of these discontinuities, and therefore of potential faults, to be deduced therefrom. The analysis is conventionally carried out either in the time domain or in the frequency domain. These methods are referred to by the acronyms TDR (for time domain reflectometry) and FDR (for frequency domain reflectometry).

The invention relates to the field of application of methods for diagnosing wires by reflectometry and applies to any type of electrical cable, in particular power transmission cables or communication cables, in fixed or mobile installations. The cable in question may be a coaxial cable, a twin-lead cable, a parallel-line cable, a twisted-pair cable or any other type of cable provided that it is possible to inject into the cable at some point a reflectometry signal and to measure its reflection at the same point or at another point.

One problem to be solved in a system for diagnosing wires relates to the attenuation that the injected signal undergoes, in the cable to be analyzed, as it propagates along the cable to a point where it is reflected. When the cable is long with respect to the wavelength of the signal, the latter undergoes, during its propagation and its back propagation, an attenuation that is dependent on the distance travelled by the signal. This attenuation is a major drawback in the step of analyzing the reflected signals, which aims to identify an amplitude peak in the result of the intercorrelation between the emitted signal and the reflected signal. Specifically, the more the signal is attenuated, the more difficult it is to detect the signature of a defect in the measurement of the reflected signal. This is especially the case if the targeted fault is a soft fault, i.e. one that corresponds to a small break in impedance, i.e. a superficial fault.

Moreover, the attenuation of the signal also depends on its frequency, it increases as the frequency of the signal increases. However, to locate a fault of small size with a sufficient precision, it is often necessary to use a high-frequency signal, because the higher the frequency, the better the resolution with which the fault may be detected and located.

To limit the attenuation of the signal during its propagation through a cable, it is therefore desirable to use an amplifier to amplify the signal before its injection, in order to limit the effects of the attenuation.

However, signal amplifiers have a non-linear behavior that leads to a saturation of the high values of the signal to be amplified. The noticeability of the presence of this non-linear behavior increases as the peak-to-average power ratio (or PAPR) of the signal to be amplified increases. This is in particular the case with multi-carrier signals such as OFDM (orthogonal frequency division multiplexing), MCTDR (multi-carrier time domain reflectometry) and OMTDR (orthogonal multi-carrier time domain reflectometry) signals, which are commonly used in reflectometry systems. The non-linear effect of an amplifier is also due to a frequency selectivity in the behavior of the various components of the amplifier.

This non-linear behavior decreases the signal-to-noise ratio of the measurements carried out and causes spreading of the spectrum of the signal. The decrease in the signal-to-noise ratio has an adverse effect on the precision of the detection of faults, whereas the spreading of the spectrum leads to problems with occupation, by the signal injected into the cable, of frequency bands that are reserved for another use.

The invention aims to provide a solution allowing the non-linear effect of an amplifier to be corrected while limiting the general bulk of the reflectometry device, which is intended to be integrated into a piece of portable equipment.

A first solution that allows the non-linear effect of an amplifier to be compensated for consists in carrying out a predistortion of the signal to be amplified by sampling a fraction of the signal output from the amplifier and delivering said fraction to the signal generator. This fed-back signal makes it possible to estimate the function to be applied to the signal to be generated, before its injection, in order to compensate for the non-linear effect of the amplifier. This correction function is, for example, defined using a linear combination of Volterra series orthogonal polynomials. Documents [1] and [2] give two examples of definition of a function that may be used to predistort a signal.

One drawback of this method is that it requires the signal generator to comprise a correcting loop, this requiring additional components, and in particular an additional analog-digital converter for converting the signal output from the amplifier before it is delivered to the module tasked with computing the predistortion function, to be added to the system. The addition of additional components has the drawback of increasing the bulk and power consumption of the resulting system.

Another solution consists in carrying out a post-distortion of the amplified signal before its injection into the cable. The post-distortion consists in removing the non-linear interference on reception. This is for example done using non-linear filters produced, as in the case of the predistortion, using Volterra series or orthogonal polynomials. This technique allows the non-linear interference to be corrected but has no effect on the spectral spreading. Furthermore, the estimation of post-distortion parameters is less precise because of the signal-to-noise ratio on reception, which normally is much lower than that on transmission.

The invention proposes a reflectometry system comprising an amplifier of the signal to be injected into the cable to be analyzed and that incorporates a mechanism for correcting for the non-linear effect of the amplifier without significantly increasing the bulk of the system by limiting the number of additional components to be incorporated with respect to a system without correction of the non-linear effect.

The subject of the invention is thus a reflectometry system for analyzing faults in a transmission line, comprising:
a digital-signal generator,
a first converter for converting the digital signal into an analog signal, an amplifier of the analog signal,
a means for injecting the amplified signal into the transmission line,
a means for sampling the signal back propagated through the transmission line,
a second converter for converting the sampled signal into a digital signal, an output of the amplifier being connected to an input of the second converter,
a device for predistorting the signal to be generated, configured to compute a function for compensating for the non-linear effect of the amplifier and to apply the compensation function to the signal to be generated, the compensation function being computed at least from the signal measured at the output from the second converter,
a first connecting/disconnecting device connecting an output of the amplifier and an input of the means for injecting the amplified signal, the first connecting/disconnecting device being able to be controlled to open position during a first phase of calibrating the signal, during which phase the compensation function is computed, and to closed position during a second phase of injecting the calibrated signal into the transmission line, a correlator for correlating the generated digital signal and the digital signal obtained as output from the second converter.

In one particular variant embodiment, the system according to the invention comprises a second connecting/disconnecting device connecting an output of the amplifier and an input of the second converter, the second connecting/disconnecting device being able to be controlled to closed position during the first phase of calibrating the signal.

According to one particular aspect of the invention, the second connecting/disconnecting device is able to be controlled to open position during the second phase of injecting the calibrated signal into the transmission line.

According to one particular aspect of the invention, the predistorting device is placed between an output of the second converter and an input of the signal generator.

According to one particular aspect of the invention, the system according to the invention comprises a deciding unit configured to estimate, during the calibrating phase, a level of distortion of the signal output from the amplifier, due to the non-linear effect of the amplifier, and to control the first connecting/disconnecting device and/or the second connecting/disconnecting device depending on the estimated level of distortion in order to activate the phase of injecting the signal into the transmission line.

According to one particular aspect of the invention, the deciding unit comprises a means for evaluating the frequency spectrum of the signal output from the second converter and estimating the level of distortion of the signal depending on at least one characteristic of the evaluated frequency spectrum.

According to one particular aspect of the invention, the level of distortion is estimated by comparing the width of the evaluated frequency spectrum with an expected frequency-spectrum width.

According to one particular aspect of the invention, the correlator comprises a device for computing a Fourier transform and said means for evaluating the frequency spectrum of the signal comprises said device for computing a Fourier transform.

According to one particular aspect of the invention, the system according to the invention comprises an attenuator placed between an output of the amplifier and an input of the second converter.

According to one particular aspect of the invention, the system according to the invention comprises a device for automatically controlling gain, placed between the means for sampling the back-propagated signal and the second converter

According to one particular aspect of the invention, the means for injecting a signal into the transmission line and the means for sampling the back-propagated signal are a first directional coupler.

According to one particular aspect of the invention, the system according to the invention comprises a second directional coupler placed between the means for sampling the back-propagated signal and an input of the second converter, and arranged to connect an output of the amplifier to an input of the second converter.

According to one particular aspect of the invention, the system according to the invention comprises a device for analyzing the results produced by the correlator with a view to analyzing the presence of faults on the transmission line.

Other features and advantages of the present invention will become more clearly apparent on reading the following description with reference to the appended drawings, which show:

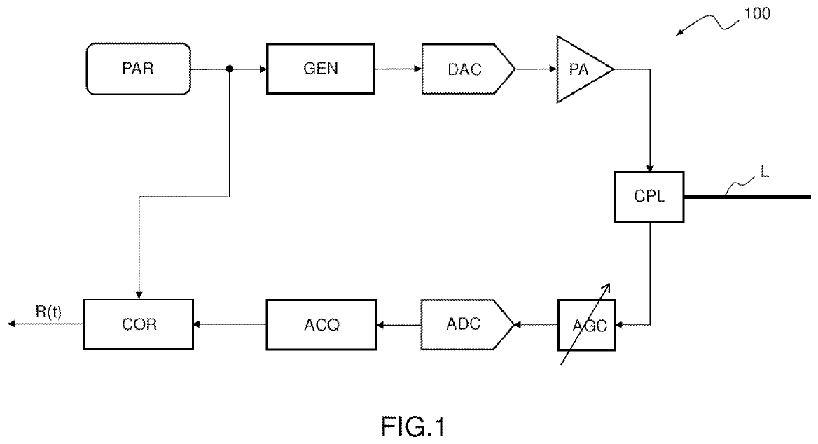

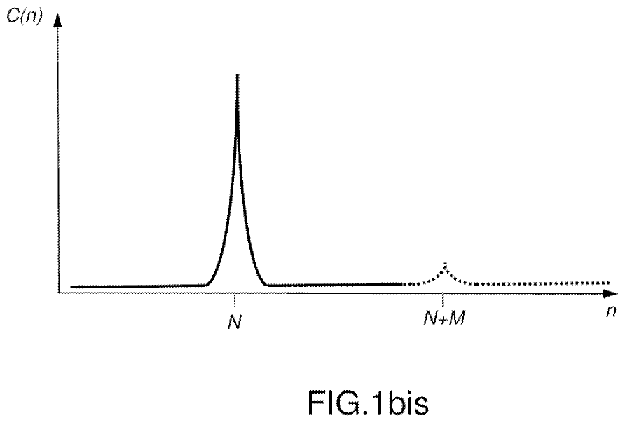

FIG. 1, a schematic of a reflectometry system incorporating an amplifier of the signal to be injected into a transmission line,

FIG. 1b is, an example of a reflectogram obtained with a reflectometry system not incorporating any amplifier,

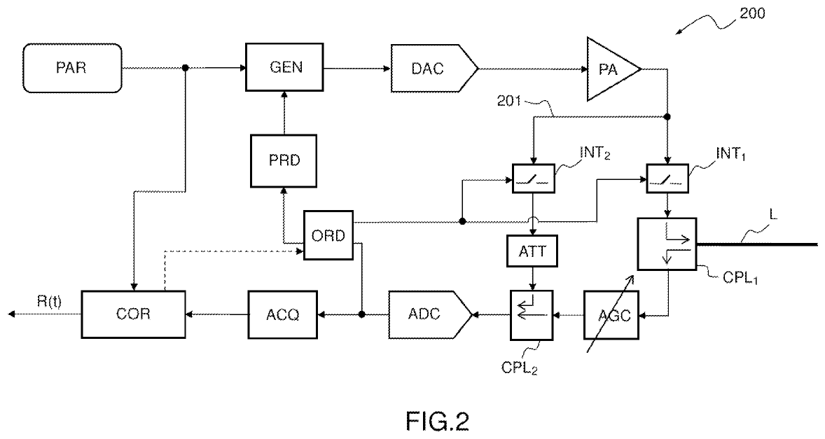

FIG. 2, a schematic of a reflectometry system modified according to the invention to compensate for the non-linear effect of the signal amplifier,

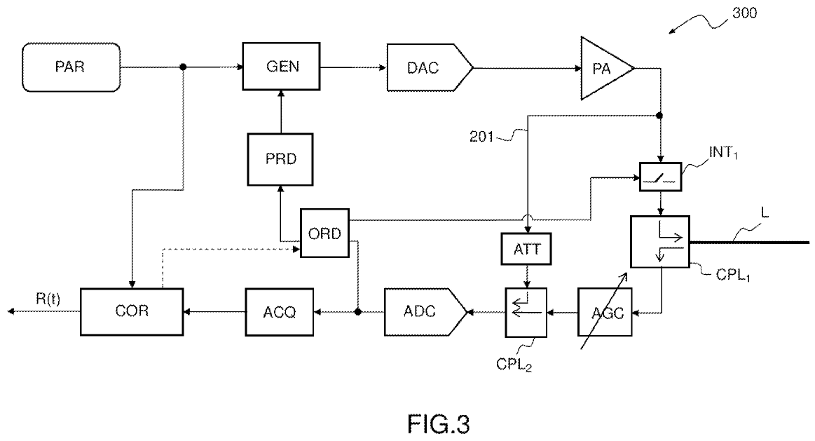

FIG. 3, a schematic of a reflectometry system according to one variant embodiment of the invention.

FIG. 1 shows a schematic of a system 100, for analyzing faults in a transmission line L by time-domain reflectometry, incorporating a computation of the intercorrelation between the signal injected into the line and the signal measured after its back propagation through the line.

Such a system mainly comprises a generator GEN that generates a reference signal based on parameters PAR defining the waveform of the signal. The generated digital reference signal is converted analogly via a digital-analog converter DAC, is amplified by an amplifier PA, for example a power amplifier, then is injected at a point on the transmission line L by means of a directional coupler CPL. The signal propagates along the line and is reflected from any singularities that the latter contains. In the absence of fault on the line, the signal is reflected from the end of the line if the termination of the line is not matched. In the presence of a fault on the line, the signal is partially or completely reflected from the impedance discontinuity caused by the fault. The reflected signal back propagates to a measurement point, which may be common to point of injection or different. The back-propagated signal is measured via the directional coupler CPL then converted digitally by an analog-digital converter ADC. A device AGC for automatically controlling gain allows the amplitude of the signal to be adjusted to the dynamic range of the analog-digital converter ADC. An acquisition ACQ is carried out by taking, for example, an average of the signal over a plurality of periods. A correlation COR is then made between the measured digital signal and a copy of the digital signal generated before injection, in order to produce a time-domain reflectogram R(t) corresponding to the intercorrelation between the two signals.

As is known in the field of time-domain reflectometry diagnosing methods, the position d_{DF} of a fault in the cable L, in other words its distance to the point of injection of the signal, may be obtained directly by measuring, on the computed time-domain reflectogram R(t), the time t_{OF} between the first amplitude peak observed in the reflectogram and the amplitude peak corresponding to the signature of the soft defect.

FIG. 1b is shows an example of a reflectogram C(n) obtained without using an amplifier PA, in which reflectogram a first amplitude peak is observed at an abscissa N and a second amplitude peak is observed at an abscissa N+M. The first amplitude peak corresponds to the reflection of the signal at the point of injection into the cable, whereas the second peak corresponds to the reflection of the signal from a discontinuity caused by a soft fault. It will be noted that the amplitude of the second peak is greatly attenuated because of the absence of amplifier.

Various known methods may be used to determine the position d_{DF} of the fault in the cable. A first method consists in applying the relationship relating distance and time: d_{DF}=V_{g}·t_{DF} where V_{g} is the speed of propagation of the signal through the cable. Another possible method consists in applying a proportionality relationship of the type d_{DF}/t_{DF}=L_{c}/t₀ where L_{c} is the length of the cable and t₀ is the time, measured on the reflectogram, between the amplitude peak corresponding to the impedance discontinuity at the point of injection and the amplitude peak corresponding to the reflection of the signal from the end of the cable.

Thus, based on analysis of the reflectogram R(t), it is possible to deduce therefrom information on the presence and location of faults.

The transfer function of a power amplifier PA may be approximated using a polynomial of order N. By way of illustration, a transfer function based on a polynomial of order equal to 5 will be considered:

yₙ=a₁xₙ+a₃xₙ³+a₅xₙ⁵

In the preceding equation, xₙ represents the signal input into the amplifier PA and yₙ represents the signal output from the amplifier PA. The values of the coefficients of the transfer function depend on the degree of saturation of the power amplifier PA.

When the signal amplified by the power amplifier PA undergoes a distortion, this leads to broadening or spreading of the spectrum of the signal. This spectral spreading results from the multiplication of the signal Xₙ by itself during its amplification, this being equivalent to a convolution in the spectral domain. For example, the term xₙ³ in the aforementioned transfer function induces a spectral component with a bandwidth that is three times larger in the signal than the bandwidth of the frequency band occupied by the signal xₙ before amplification. The level of this spectral component is defined by the factor a₃, which is a function of the degree of saturation of the amplifier PA.

An additional problem due to the non-linear behavior of the amplifier PA relates to non-linear interference. This occurs because the non-linearity is combined with the filtering functions implemented by the various components of the reflectometry system. For example, the signal generator GEN may comprise a forming filter. The digital-analog converter DAC, the directional coupler CPL and the analog-digital converter ADC also have transfer functions that may be likened to filters. These filters may be represented by linear combinations of the digital samples to be injected. The filter is, for example, represented by the following relationship:

$${x}_{n} = {\sum }_{i = 0}^{M} {b}_{i} {s}_{n - i}$$

The non-linear interference is the result of the combination of the linear functions implemented by the various components of the system with the non-linear function characterizing the amplifier PA.

The implementation of a device allowing an amplifier PA that works in it saturation zone to be linearized is very expensive in terms of hardware resources. Such a device generally requires a feedback loop to be installed in the transmitter. This loop is essentially composed of a coupler, of an attenuator and of a high-precision analog-digital converter, working at least at the same speed as the digital-analog converter of the reflectometry system. The bulk of this hardware, which may represent up to 50% of the additional analog bulk, is too high in the context of a low-cost or low-consumption or quite simply on-board reflectometry system.

FIG. 2 shows a schematic of a system 200 for analyzing faults in a transmission line L, according to the invention. More generally, the system 200 is suitable for implementing a technique for detecting and/or locating faults by reflectometry.

The operation of the system 200 comprises two successive phases, a calibrating first phase in which the generated signal is corrected in order to take into account the non-linear effect of the amplifier PA, then a processing second phase in which the signal is injected into the transmission line L and a reflectometry analysis is applied to the back-propagated signal sampled at the point of injection.

The system 200 comprises the same elements as already described with reference to FIG. 1, namely a signal generator GEN, a digital-analog converter DAC, an amplifier PA, a first directional coupler CPL₁ for injecting the signal into the transmission line L and sampling the back-propagated signal, a device AGC for automatically controlling gain, an analog-digital converter ADC, an acquiring module ACQ and a correlator COR.

The system 200 furthermore comprises a predistorting module PRD configured to correct the generated signal in order to compensate for the non-linear effect of the amplifier PA. The predistorting module is arranged between the signal generator GEN and the output of the analog-digital converter ADC.

The system 200 also comprises a first on/off switch INT₁ positioned on the path between the output of the amplifier PA and the first directional coupler CPL₁. When the on/off switch INT₁ is in open position, the signal output from the amplifier PA is not injected into the transmission line L. When the on/off switch INT₁ is in closed position, the signal output from the amplifier PA is injected into the transmission line L.

The system 200 also comprises a connection 201 between the output of the amplifier PA and the input of the analog-digital converter ADC. This connection 201 is, for example, achieved by means of a second directional coupler CPL₂ positioned between the device AGC for automatically controlling gain and the analog-digital converter ADC. In a first embodiment of the invention, this connection 201 may be permanent. In a second embodiment of the invention, a second on/off switch INT₂ may be positioned in this connection 201. When the second on/off switch INT₂ is in closed position, the signal output from the amplifier PA is injected as input into the analog-digital converter ADC directly.

The first on/off switch INT₁ and/or the second on/off switch INT₂ may be replaced by any equivalent connecting/disconnecting device, for example any other type of switch. The connection 201 and/or the connection between the amplifier PA and the directional coupler CPL₁ may also be achieved manually by connecting/disconnecting respective links.

In one embodiment of the invention, an attenuator ATT is positioned on the path of the connection 201 in order to ensure the amplitude of the signal, which has been amplified by the amplifier PA, lies within the dynamic range of the analog-digital converter ADC. The attenuator ATT makes it possible to prevent overload of the analog-digital converter ADC. In one particular embodiment, it may be merged with the second directional coupler CPL₂.

The system 200 also comprises a deciding unit ORD for controlling the first on/off switch INT₁ and, optionally, the second on/off switch INT₂ depending on an estimation of the level of distortion of the amplified signal output from the amplifier PA, the distortion being due to the non-linear effect of the amplifier PA.

The system 200 according to the invention operates in the following manner. In a calibrating first phase, the first on/off switch INT₁ is controlled to open position by the deciding unit ORD. If the second on/off switch INT₂ is present, it is controlled to closed position by the deciding unit ORD.

The generator GEN generates a digital signal that is converted analogly then amplified by the amplifier PA. The amplified signal passes through the connection 201 in order to be delivered as input to the analog-digital converter. It is beforehand optionally attenuated if an attenuator is present on the path 201. The signal is converted digitally then is transmitted to the predistorting module PRD, which estimates a corrective function to be applied to the signal to be generated, in order to correct for the non-linear effect of the amplifier PA and to obtain an amplified signal with a decreased level of distortion. The predistorting module PRD implements, for example, a function that models a nonlinear system, for example a function constructed using a linear combination of Volterra series. Such a function is applied to the signal to be generated in order to modify it so as to compensate for the non-linear effect of the amplifier PA.

The corrective function to be applied by the predistorting module PRD to compensate for the non-linear effect of the amplifier PA may be modelled using the following relationship:

$${s}_{n}^{′} = {\sum }_{i = 0}^{M} {q}_{i} {s}_{n + i} + {\sum }_{i = 0}^{M} {\sum }_{j = 0}^{M} {q}_{i , j} {s}_{n + i} {s}_{n + j} + {\sum }_{i = 0}^{M} {\sum }_{j = 0}^{M} {\sum }_{k = 0}^{M} {q}_{i , j , k} {s}_{n + i} {s}_{n + j} {s}_{n + k} + ⋯$$

In this equation, the samples sₙ₊ᵢ represent the generated digital signal before predistortion and s′ₙ is the signal sₙ corrected with the predistortion function. The coefficients qᵢ are the parameters of the corrective function. The coefficients qᵢ may be determined via a method for decreasing square error, such as the LMS (least mean squares) or RLS (recursive least squares) method or any other equivalent method. The optimal set of parameters qᵢ is the set that minimizes the error, ∥sₙ−rₙ∥², where rₙ is the signal output from the analog-digital converter ADC and ∥ ∥² is the modulus function raised to the power of two. The coefficients of the predistortion function are thus determined so as to minimize the error between the signal output from the amplifier PA (measured at the output of the converter ADC) and the generated signal sₙ before predistortion, i.e. the signal not distorted by the effect of the amplifier PA.

Another way of modelling the system consists in using a series of orthogonal polynomials. In this case, the signal output from the amplifier is modelled via the following relationship:

$${s}_{n}^{′} = {\sum }_{i = 0}^{M} {q}_{i} {P}^{( i )} ( {s}_{n} )$$

the qᵢ being coefficients of the predistortion function and P⁽ⁱ⁾(⋅) being an orthogonal polynomial of order i. Anyone skilled in the art will be able to compute the predistortion function from the indications given in references [1] or [2], or using any other known alternative method that may be used to correct the signal to be generated in light of a prior evaluation of the level of distortion affecting the signal output from the amplifier PA.

In one embodiment of the invention, the computation of the predistortion function and the correction of the signal to be generated may be performed iteratively. In other words, once the generated signal has been corrected a first time by the predistorting module, the on/off switch INT₁ may be kept in closed position in order to allow a new iteration of computation of the predistortion function to be carried out.

In one embodiment of the invention, the deciding unit ORD measures, in each iteration, the level of distortion of the signal sampled at the output of the analog-digital converter ADC and decides, when the level of distortion is acceptable, to control the on/off switch INT₁ to closed position in order to stop the calibrating phase and start the analyzing phase.

In one particular embodiment of the invention, the level of distortion of the signal is evaluated by computing information on signal-to-noise ratio.

In another embodiment of the invention, the level of distortion of the signal is evaluated by determining the frequency spectrum of the signal output from the analog-digital converter ADC and by comparing this spectrum to the spectrum of the signal expected in the absence of distortion. In particular, the width of the spectrum may be used as characteristic for comparison. Specifically, the non-linear effect of the amplifier PA causes spreading of the spectrum of the amplified signal (as explained above). Therefore, an increase in the width of the spectrum of the amplified signal with respect to the expected signal gives an indication of the level of distortion.

In one particular embodiment of the invention, the frequency spectrum of the signal is determined using a Fourier-transform module present within the correlator COR. Specifically, the correlator COR applies a discrete Fourier transform to the measured signal and a discrete Fourier transform to the reference signal, then determines the product of the two results and lastly applies an inverse discrete Fourier transform to the product obtained. This process is expressed by the following formula, which gives the intercorrelation of two signals x(t) and x′(t):

c(t)=∫_{-∞}^{∞}x′(t+τ)·x*(τ)dτ=TF⁻¹{TF{x′(t)}·TF{x*(t)}}

Thus, the correlator COR already comprises a module for computing discrete Fourier transforms, which is advantageously used by the deciding unit ORD to determine the frequency spectrum of the signal.

At the end of the calibrating phase, i.e. when the measured level of distortion of the signal output from the analog-digital converter is sufficiently low, the deciding unit controls the first on/off switch INT₁ to closed position so that the amplified signal is injected into the transmission line L via the coupler CPL₁.

The back-propagated signal is sampled by the coupler CPL₁ and transmitted along the processing chain to the correlator. In the analyzing phase, the second on/off switch INT₂ may be controlled to open position or to closed position. If it is in closed position, then the signal input into the analog-digital converter ADC is the sum of the signal sampled by the coupler CPL₁ and of the signal transmitted via the connection 201. In such a case, the reflectogram obtained as output from the correlator COR comprises a first amplitude peak that corresponds to the signal generated and transmitted via the connection 201 and possibly other amplitude peaks corresponding to faults in the transmission line, from which faults the signal is reflected. The first amplitude peak may be used as reference to estimate the distance between the point of injection of the signal and a potential fault. Thus the second on/off switch INT₂ is optional, because keeping the connection 201 during the analyzing phase does not disrupt the operation of the fault-analyzing system.

During the analyzing phase, estimation of the predistortion function is stopped but the predistorting module PRD continues to correct the generated signal with the predistortion function estimated during the calibrating phase.

In one particular embodiment of the invention, the system 200 may be used as a system for transmitting data via the transmission line L. In this case, the generated signal is no longer a stationary signal but any signal that conveys data to be transmitted.

FIG. 3 shows one variant 300 of the system 200, in which, as explained above, the second on/off switch INT₂ is optional.

The system according to any one of the variants of the invention may be implemented by an electronic board on which the various components are placed. The board may be connected to the cable to be analyzed by a coupling means CPL₁ that may be a capacitive or inductive directional coupler or even an ohmic connection. The coupling device may be produced using physical connectors that connect the signal generator to the cable or using contactless means, for example a metal cylinder the inside diameter of which is substantially equal to the outside diameter of the cable and that couples capacitively to the cable.

The on/off switches INT₁,INT₂ may be produced using any component able to be controlled to open or closed position in order to open or close a connection between two components. They may for example take the form of any other type of switch or any other equivalent component.

Furthermore, a processing unit, such as a computer, personal digital assistant or other equivalent electronic or computational device may be used to control the system according to the invention and to display, on a human-machine interface, the results of the computations carried out by the correlator COR and in particular the reflectogram R(t) and/or the information on the detection and location of faults in the cable.

The method according to the invention, and in particular the digital processing modules GEN, PRD, ORD, ACQ, COR, may be implemented in a processor, which may optionally be an on-board processor, or in a specific device. The processor may be a generic processor, a specific processor, an application-specific integrated circuit (ASIC) or a field programmable gate array (FPGA). The device according to the invention may use one or more dedicated electronic circuits or a general-use circuit. The technique of the invention may be carried on a reprogrammable computing machine (a processor or a microcontroller for example) that executes a program comprising a sequence of instructions, or on a dedicated computing machine (for example a set of logic gates such as an FPGA or an ASIC, or any other hardware module).

The reflectometry system according to the invention may comprise, within the same device, both components able to generate the reference signal and to inject it into one or more transmission lines and components able to measure the back-propagated signal and to carry out the computations required to generate a reflectogram. Alternatively, these two portions may be implemented in two separate devices, each device being independently connected to the cable to be analyzed.

The invention has the advantage of using the basic analog-digital converter ADC present in any reflectometry system in a loop for predistorting the signal to be generated, in order to compensate for the non-linear effect of the amplifier PA.

Thus, the overall bulk of the system is limited because it requires only the addition of two digital processing modules PRD,ORD (which may be located together in a single module) and of one on/off switch INT₁.

The invention allows the signal to be generated to be calibrated in a calibrating first phase then the calibrated signal to be injected into the transmission line L to be analyzed without disrupting the overall operation of the system.

### REFERENCES

[1] H. Qian, S. Yao, H. Huang and W. Feng, A Low-Complexity Digital Predistortion Algorithm for Power Amplifier Linearization, in IEEE Transactions on Broadcasting, vol. 60, no. 4, pp. 670-678, Dec. 2014
[2] Y. Liu, W. Pan, S. Shao and Y. Tang, A General Digital Predistortion Architecture Using Constrained Feedback Bandwidth for Wideband Power Amplifiers, in IEEE Transactions on Microwave Theory and Techniques, vol. 63, no. 5, pp. 1544-1555, May 2015

1. A reflectometry system for analyzing faults in a transmission line (L), comprising:
a digital-signal generator (GEN),
a first converter (DAC) for converting the digital signal into an analog signal, an amplifier (PA) of the analog signal,
a means (CPL₁) for injecting the amplified signal into the transmission line, a means (CPL₁) for sampling the signal back propagated through the transmission line,
a second converter (ADC) for converting the sampled signal into a digital signal, an output of the amplifier (PA) being connected to an input of the second converter (ADC),
a device (PRD) for predistorting the signal to be generated, configured to compute a function for compensating for the non-linear effect of the amplifier (PA) and to apply the compensation function to the signal to be generated, the compensation function being computed at least from the signal measured at the output from the second converter (ADC),
a first connecting/disconnecting device (INT₁) connecting an output of the amplifier (PA) and an input of the means (CPL₁) for injecting the amplified signal, the first connecting/disconnecting device (INT₁) being able to be controlled to open position during a first phase of calibrating the signal, during which phase the compensation function is computed, and to closed position during a second phase of injecting the calibrated signal into the transmission line,
a correlator (COR) for correlating the generated digital signal and the digital signal obtained as output from the second converter (ADC).

2. The reflectometry system as claimed in claim 1, comprising a second connecting/disconnecting device (INT₂) connecting an output of the amplifier (PA) and an input of the second converter (ADC), the second connecting/disconnecting device (INT₂) being able to be controlled to closed position during the first phase of calibrating the signal.

3. The reflectometry system as claimed in claim 2, wherein the second connecting/disconnecting device (INT₂) is able to be controlled to open position during the second phase of injecting the calibrated signal into the transmission line (L).

4. The reflectometry system as claimed in claim 1, wherein the predistorting device (PRD) is placed between an output of the second converter (ADC) and an input of the signal generator (GEN).

5. The reflectometry system as claimed in claim 1, comprising a deciding unit (ORD) configured to estimate, during the calibrating phase, a level of distortion of the signal output from the amplifier (PA), due to the non-linear effect of the amplifier (PA), and to control the first connecting/disconnecting device (INT₁) and/or the second connecting/disconnecting device (INT₂) depending on the estimated level of distortion in order to activate the phase of injecting the signal into the transmission line.

6. The reflectometry system as claimed in claim 5, wherein the deciding unit (ORD) comprises a means for evaluating the frequency spectrum of the signal output from the second converter (ADC) and estimating the level of distortion of the signal depending on at least one characteristic of the evaluated frequency spectrum.

7. The reflectometry system as claimed in claim 6, wherein the level of distortion is estimated by comparing the width of the evaluated frequency spectrum with an expected frequency-spectrum width.

8. The reflectometry system as claimed in claim 6, wherein the correlator (COR) comprises a device for computing a Fourier transform and said means for evaluating the frequency spectrum of the signal comprises said device for computing a Fourier transform.

9. The reflectometry system as claimed in claim 1, comprising an attenuator (ATT) placed between an output of the amplifier (PA) and an input of the second converter (ADC).

10. The reflectometry system as claimed in claim 1, comprising a device (AGC) for automatically controlling gain, placed between the means (CPL₁) for sampling the back-propagated signal and the second converter (ADC)

11. The reflectometry system as claimed in claim 1, wherein the means for injecting a signal into the transmission line and the means for sampling the back-propagated signal are a first directional coupler (CPL₁).

12. The reflectometry system as claimed in claim 1, comprising a second directional coupler (CPL₂) placed between the means (CPL₁) for sampling the back-propagated signal and an input of the second converter (ADC), and arranged to connect an output of the amplifier (PA) to an input of the second converter (ADC).

13. The reflectometry system as claimed in claim 1, comprising a device for analyzing the results produced by the correlator (COR) with a view to analyzing the presence of faults on the transmission line (L).
